(19) United States
(12) Patent Application Publication
(10) Pub. No.: US 2006/0021571 A1
(43) Pub. Date: Feb. 2, 2006

(54) Vacuum pump line with nickel-chromium heater layer

(75) Inventors: Sheng-Hsiung Tseng, Tainan City (TW); Yao-Pin Huang, Tainan City (TW); Ming-Huang Wu, Kaohsiung City (TW); Chang-Jung Su, Changhua County (TW); Stone Shyr, Pingeung City (TW); Yuan-Hung Chang, Kaohsiung City (TW); He-Ming Chuang, Madou Township (TW)

Correspondence Address: TUNG & ASSOCIATES, Suite 120, 838 W. Long Lake Road, Bloomfield Hills, MI, 48302, US

(73) Assignee: Taiwan Semiconductor Manufacturing Co., Ltd.

(21) Appl. No.: 10/901,284

(22) Filed: Jul. 28, 2004

(51) Int. Cl. C23C 16/00

(52) U.S. Cl. 118/715; 156/345.29

(57) ABSTRACT

A vacuum pump line for a process chamber is disclosed. The vacuum pump line includes a pump line wall and a heater layer comprising a nickel-chromium alloy surrounding the pump line wall for heating the pump line wall. A method for fabricating a pump line for a process chamber is also disclosed.

### FIELD OF THE INVENTION

The present invention relates to thermal oxidation furnaces, CVD chambers and the like for forming material layers on a semiconductor wafer substrate during the fabrication of integrated circuits. More particularly, the present invention relates to a vacuum pump line having an alloyed nickel-chromium heater layer and connects a furnace, CVD chamber or the like to a vacuum pump to prevent condensation of residual powders in the vacuum pump line during evacuation of the furnace or chamber.

### BACKGROUND OF THE INVENTION

In the semiconductor production industry, various processing steps are used to fabricate integrated circuits on a semiconductor wafer. These steps include the deposition of layers of different materials including metallization layers, passivation layers and insulation layers on the wafer substrate, as well as photoresist stripping and sidewall passivation polymer layer removal. In modern memory devices, for example, multiple layers of metal conductors are required for providing a multi-layer metal interconnection structure in defining a circuit on the wafer. Chemical vapor deposition (CVD) processes are widely used to form layers of materials on a semiconductor wafer. Other processing steps in the fabrication of the circuits include formation of a photoresist or other mask such as titanium oxide or silicon oxide, in the form of the desired metal interconnection pattern, using standard lithographic techniques; subjecting the wafer substrate to a dry etching process to remove the conducting layer from the areas not covered by the mask, thereby leaving the metal layer in the form of the masked pattern; removing the mask layer using reactive plasma and chlorine gas, thereby exposing the top surface of the metal interconnect layer; cooling and drying the wafer substrate by applying water and nitrogen gas to the wafer substrate; and removing or stripping polymer residues from the wafer substrate.

CVD processes include thermal deposition processes, in which a gas is reacted with the heated surface of a semiconductor wafer substrate, as well as plasma-enhanced CVD processes, in which a gas is subjected to electromagnetic energy in order to transform the gas into a more reactive plasma. In CVD processes, as well as furnace processes such as silicon nitride processes, for example, exhaust gas that contains both reaction products and unreacted gas is discharged through an exhaust pipe system. During a vertical furnace silicon nitride process, for example, a reaction by-product such as ammonium chloride (NH₄Cl) in the form of fine powder can easily deposit on any cold surface in the furnace or in the ducting system for the furnace.

A conventional CVD or furnace processing system includes a chamber for receiving a wafer. Process gases are introduced into the chamber to deposit material layers on the wafer. After completion of the process, the exhaust gases are evacuated from the chamber through an exhaust system including a vacuum pump line that typically includes valves and a vacuum pump. A tape heater typically surrounds the portion of the vacuum pump line extends between the chamber and the vacuum pump. During the exhaust evacuation process, the tape heater heats the interior of the vacuum pump line to maintain the exhaust gases in the gaseous state. A trap may be provided in the line to condense the exhaust gas into particles and trap the particles for removal.

If particles condense and adhere to the inside of the vacuum pump line, the valves, then the vacuum pump and other components in the exhaust system must be cleaned. Cleaning of the exhaust system typically involves troublesome operations including the removal of exhaust pipes, valves and vacuum pump, as well as cleaning of the pump. Moreover, if the reaction products are corrosive, they will have a tendency to corrode the exhaust pipes. Therefore, adhesion of the reaction products to the interior surfaces of the vacuum pump line and other components of the exhaust system must be minimized.

Use of a conventional tape heater to heat the vacuum pump line is attended by several drawbacks. First, the tape heater is expensive to install. Second; the tape heater is coiled around the line, forming gaps along the line. Therefore, the tape heater is typically incapable of uniformly heating the interior of the line. Consequently, exhaust gases may have a tendency to condense as powder on the lower-temperature areas of the line interior. Third, the tape heater is easily damaged and cannot be fixed but must be replaced. This introduces additional expense into maintenance of the CVD or furnace processing system. Fourth, disassembly of the tape heater for periodic maintenance is difficult.

Accordingly, a vacuum pump line with a novel heater layer for a CVD, furnace or other processing system is needed which is characterized by substantially uniform heating and can be repaired as needed to reduce the costs associated with maintenance of the CVD or furnace processing system.

An object of the present invention is to provide a vacuum pump line with a novel heater layer suitable for connecting a process chamber to a vacuum pump.

Another object of the present invention is to provide a vacuum pump with a novel heater layer having a nickel-chromium alloy.

Still another object of the present invention is to provide a novel vacuum pump line having a heater layer which is capable of providing substantially uniform heating capability along substantially the entire length of the vacuum pump line.

Yet another object of the present invention is to provide a vacuum pump line having a nickel-chromium heating layer which can be repaired as needed.

A still further object of the present invention is to provide a vacuum pump line having a novel cylindrical heater layer which is capable of applying substantially uniform heat to the vacuum pump line to prevent condensation of exhaust gases during transit through the line.

Another object of the present invention is to provide a method of fabricating a vacuum pump line having a heater layer, which method includes providing a pump line wall and may include sputtering or otherwise depositing a nickel-chromium alloy layer on the pump line wall or on an isolation layer provided on the

### SUMMARY OF THE INVENTION

The present invention is generally directed to a novel vacuum pump line with heater layer suitable for a vacuum pump line of a process chamber. The vacuum pump line typically has a multi-layer construction including a heater layer sandwiched between a pair of isolation layers. The heater layer is typically a nickel-chromium alloy and cylindrical in configuration. As exhaust gases are distributed from a process chamber, through the vacuum pump line to a vacuum pump, for example, the heater layer is capable of distributing heat substantially uniformly along the vacuum pump line to prevent condensation of exhaust gases during transit through the line.

The present invention further includes a method of fabricating a vacuum pump line having a heater layer. The method includes providing a pump line wall and providing a nickel-chromium alloy heater layer in thermal contact with the pump line wall. Typically, an isolation layer is interposed between the heater layer and the pump line wall.

### BRIEF DESCRIPTION OF THE DRAWINGS

The invention will now be described, by way of example, with reference to the accompanying drawings, in which:

FIG. 1 is a perspective view, partially in section, of an illustrative embodiment of the vacuum pump line with nickel-chromium heater layer of the present invention;

FIG. 2 is an enlarged cross-sectional view, taken along section line 2 in FIG. 1;

FIG. 3 is a schematic of a process chamber, with the vacuum pump line of the present invention connecting the process chamber to a vacuum pump in typical application of the invention; and

FIG. 4 is a flow diagram illustrating sequential process steps carried out according to a method of fabricating a vacuum pump line having a heater layer according to the present invention.

### DETAILED DESCRIPTION OF THE INVENTION

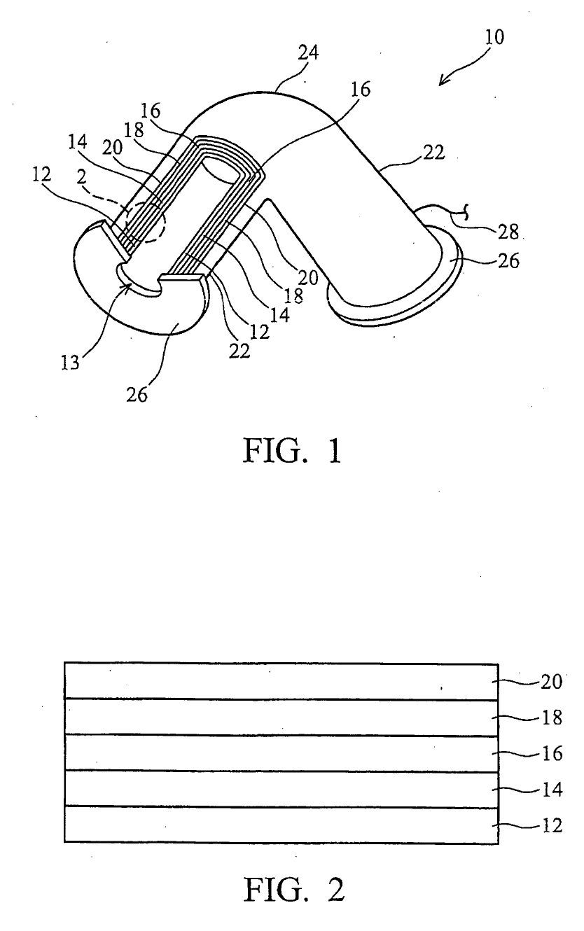

Referring initially to FIGS. 1 and 2, an illustrative embodiment of the vacuum pump line of the present invention is generally indicated by reference numeral 10. The vacuum pump line 10 shown in FIG. 1 includes a pair of straight segments 22 which are joined at a bend 24 and positioned in generally perpendicular relationship to each other. However, it is understood that the vacuum pump line 10 may alternatively have a straight configuration or any other configuration which is consistent with the use requirements of the vacuum pump line 10. A gas flow bore 13 traverses the length of the vacuum pump line 10. An attachment flange 26 may be provided on the end of each straight segment 22 for purposes which will be hereinafter described.

As shown in FIGS. 1 and 2, the vacuum pump line 10 includes a typically cylindrical pump line wall 12 which is typically stainless steel and forms the interior surface of the vacuum pump line 10, inside the gas flow bore 13. An inner isolation layer 14 encircles the pump line wall 12. The inner isolation layer 14 may be silicon dioxide, polytetrafluoroethylene (TEFLON), silicon rubber or any other suitable electrically-insulating yet thermally-conductive material.

A typically cylindrical heater layer 16 encircles the inner isolation layer 14. The heater layer 16 is preferably a metal alloy of nickel and chromium, since nickel-chromium alloys have a high electrical corrosion resistance. Preferably, the heater layer 16 is sputtered on the inner isolation layer 14 using a nickel-chromium target in a conventional physical vapor deposition (PVD) chamber. As shown in FIG. 1, a power cord 28 is provided in electrical contact with the heater layer 16. The power cord 28 is typically adapted to deliver 120 volts of electricity to the heater layer 16 to heat the heater layer 16, by ohmic resistance, to a temperature of typically about 120˜150 degrees C. in typical operation of the vacuum pump line 10, as hereinafter described.

A typically cylindrical outer isolation layer 18 encircles the heater layer 16. Like the inner isolation layer 14, the outer isolation layer 18 is typically silicon dioxide, polytetrafluoroethylene (TEFLON), silicon rubber or any other suitable electrically-insulating and thermally-conductive material. The inner isolation layer 14 and the outer isolation layer 18 electrically insulate the heater layer 16 from the remaining portion of the vacuum pump line 10. A thermal insulation layer 20, which is typically silicon rubber, encircles the outer isolation layer 18.

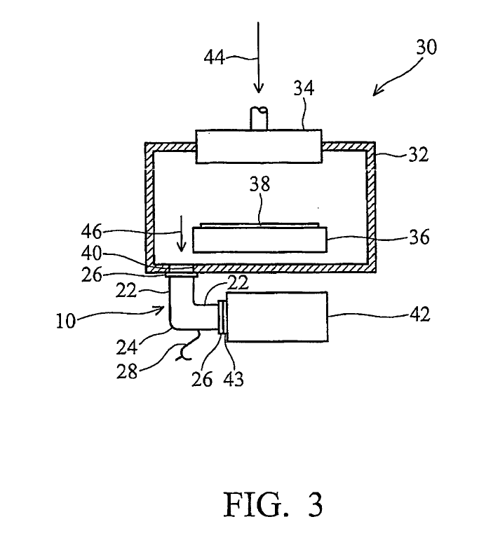

Referring next to FIG. 3, in typical application of the invention, the vacuum pump line 10 connects a process chamber 32 of a wafer processing system 30 to a vacuum pump 42. The process chamber 32 may be a CVD chamber, a processing furnace or the like typically used to deposit material layers on a wafer 38 and contains a wafer support 36 for supporting the wafer 38. A “showerhead” or gas distribution plate (GDP) 34 is provided in the top of the process chamber 32 for the introduction of process gases 44 into the process chamber 32. A valve (not shown) may be provided between the process chamber 32 and the vacuum pump line 10 and/or between the vacuum pump line 10 and the vacuum pump 42. A particle trap (not shown) may further be provided between the vacuum pump line 10 and the vacuum pump 42 for the trapping of particles therein.

An exhaust outlet opening 40 is typically provided in the bottom of the process chamber 32 for the evacuation of exhaust gases from the process chamber 32 during and/or after a process carried out on the wafer 38. Accordingly, one end of the vacuum pump line 10 is attached to the process chamber 32, with the gas flow bore 13 (FIG. 1) provided in fluid communication with the exhaust outlet opening 40 in the process chamber 32. The vacuum pump line 10 may be attached to the process chamber 32 by extending bolts (not shown) through bolt openings (not shown) provided in the attachment flange 26 and threading the bolts into registering bolt openings (not shown) provided in the process chamber 32. The opposite end of the vacuum pump line 10 is attached to the inlet of the vacuum pump 42. This may be accomplished by attaching the attachment flange 26 to a pump flange 43 provided on the vacuum pump 42, typically using bolts (not shown).

During operation of the wafer processing system 30, process gases 44 are introduced into the process chamber 32 through the GDP 34. Depending on the type of process, the process gases 44 form a material layer or layers (not shown) on the surface of the wafer 38. During and/or after completion of the process, the vacuum pump 42 draws exhaust gases 46 from the process chamber 32, through the vacuum pump line 10 to evacuate the exhaust gases from the process chamber 32. Simultaneously, electricity (typically 120 volts) is applied to the heater layer 16 (FIGS. 1 and 2) of the vacuum pump line 10, typically through the power cord 28. Accordingly, due to the ohmic or resistive losses that occur when the electrical current flows through the heater layer 16, the temperature of the heater layer 16 rises to typically about 130˜150 degrees C. This heat is transmitted by conduction through the thermally-conductive inner isolation layer 14 to the pump line wall 12. Accordingly, by convection the pump line wall 12 heats the exhaust gases 46 flowing through the gas flow bore 13 of the vacuum pump line 10. This prevents the flowing exhaust gases 46 from condensing to form powder in the vacuum pump line 10 and other elements such as valves (not shown) provided adjacent to the vacuum pump line 10. The thermal insulation layer 20 prevents excessive dissipation of heat from the heater layer 16, thus reflecting most of the heat back toward the gas flow bore 13.

Referring again to FIG. 1, it will be appreciated by those skilled in the art that the typically cylindrical design of the heater layer 16 facilitates substantially uniform heating of the pump line wall 12 throughout substantially the entire length of the vacuum pump line 10. Furthermore, in the event of damage or wearing, the heater layer 16 can be fixed by removing the vacuum pump line 10 from the wafer processing system 30, re-sputtering or depositing the heater layer 16 on the inner isolation layer 14 and re-attaching the vacuum pump line 10 to the wafer processing system 30. This eliminates the need to replace the vacuum pump line 10, resulting in cost savings to maintenance of the system 30.

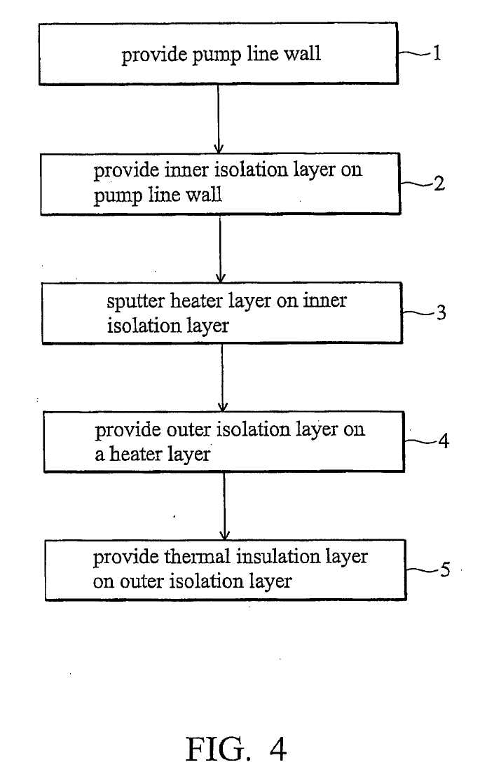

Referring next to the flow diagram of FIG. 4, a method of fabricating a vacuum pump line with heater layer of the present invention is carried out typically as follows. In step 1, a pump line wall is initially provided. The pump line wall is typically cylindrical and is preferably stainless steel. In step 2, an inner isolation layer is provided on the outer surface of the pump line wall. The inner isolation layer may be any suitable electrically-resistant and thermally-conductive material including but not limited to silicon dioxide, polytetrafluoroethylene (TEFLON) or silicon rubber. In step 3, a heater layer, typically a nickel-chromium alloy, is provided on the inner isolation layer. Preferably, the heater layer is deposited on the inner isolation layer using a conventional PVD (physical vapor deposition) metal sputtering technique. In step 4, an outer isolation layer is provided on the heater layer. The outer isolation layer may be any suitable electrically-resistant and thermally-conductive material including but not limited to silicon dioxide, polytetrafluoroethylene (TEFLON) or silicon rubber. In step 5, a thermal insulation layer is provided on the outer isolation layer. The thermal insulation layer is typically silicon rubber.

While the preferred embodiments of the invention have been described above, it will be recognized and understood that various modifications can be made to the invention and the appended claims are intended to cover all such modifications which may fall within the spirit and scope of the invention.

What is claimed is:

1. A vacuum pump line comprising:
a pump line wall; and
a heater layer comprising a nickel-chromium alloy provided in thermal contact with said pump line wall for heating said pump line wall.

2. The vacuum pump line of claim 1 wherein said pump line wall comprises stainless steel.

3. The vacuum pump line of claim 1 further comprising an inner isolation layer interposed between said pump line wall and said heater layer.

4. The vacuum pump line of claim 3 wherein said inner isolation layer is a material selected from the group consisting of silicon dioxide, polytetrafluoroethylene and silicon rubber.

5. The vacuum pump line of claim 3 further comprising an outer isolation layer surrounding said heater layer.

6. The vacuum pump line of claim 5 wherein said outer isolation layer is a material selected from the group consisting of silicon dioxide, polytetrafluoroethylene and silicon rubber.

7. The vacuum pump line of claim 5 further comprising a thermal insulation layer surrounding said outer isolation layer.

8. The vacuum pump line of claim 7 wherein said thermal insulation layer comprises silicon rubber.

9. A vacuum pump line comprising:
a generally cylindrical pump line wall;
a generally cylindrical inner isolation layer surrounding said pump line wall;
a generally cylindrical heater layer comprising a nickel-chromium alloy surrounding said inner isolation layer for heating said pump line wall; and
a generally cylindrical outer isolation layer surrounding said heater layer.

10. The vacuum pump line of claim 9 further comprising a pair of attachment flanges terminating opposite ends of said pump line wall.

11. The vacuum pump line of claim 9 wherein said pump line wall defines a pair of straight segments and a bend joining said pair of straight segments.

12. The vacuum pump line of claim 9 wherein said pump line wall is stainless steel.

13. The vacuum pump line of claim 9 wherein said inner isolation layer is a material selected from the group consisting of silicon dioxide, polytetrafluoroethylene and silicon rubber.

14. The vacuum pump line of claim 9 wherein said outer isolation layer is a material selected from the group consisting of silicon dioxide, polytetrafluoroethylene and silicon rubber.

15. The vacuum pump line of claim 9 further comprising a thermal insulation layer surrounding said outer isolation layer.

16. The vacuum pump line of claim 15 wherein said thermal insulation layer comprises silicon rubber.

17. A method of fabricating a vacuum pump line, comprising:
providing a pump line wall; and
providing a heater layer comprising a nickel-chromium alloy in thermal contact with said pump line wall.

18. The method of claim 17 wherein said providing a heater layer comprises sputtering said heater layer.

19. The method of claim 18 further comprising providing an inner isolation layer around said pump line wall and wherein said sputtering said heater layer comprises sputtering said heater layer on said inner isolation layer.

20. The method of claim 19 further comprising providing an outer isolation layer around said heater layer and a thermal insulation layer around said outer isolation layer.
